(19) United States
(12) Patent Application Publication
(10) Pub. No.: US 2008/0233695 A1
(43) Pub. Date: Sep. 25, 2008

(54) Integration method of inversion oxide (TOXinv) thickness reduction in CMOS flow without added pattern

(75) Inventors: Shashank S. Ekbote, Allen, TX (US); F. Scott Johnson, Richardson, TX (US)

Correspondence Address: TEXAS INSTRUMENTS INCORPORATED, P O BOX 655474, M/S 3999, DALLAS, TX, 75265, US

(73) Assignee: Texas Instruments Inc.

(21) Appl. No.: 11/725,417

(22) Filed: Mar. 19, 2007

(51) Int. Cl. H01L 21/8238

(52) U.S. Cl. 438/221; 257/E21.632

(57) ABSTRACT

A method of manufacturing a CMOS semiconductor comprising, forming shallow trench isolation regions in a workpiece, depositing a gate oxide layer on top of the workpiece, depositing a polysilicon layer on top of the gate oxide, performing VT_{N} patterning, performing first series of adjusted implantations, performing post implantation cleaning, performing VT_{P} patterning, performing a second series of adjusted implantations, performing the post implantation cleaning, performing a well implant damage anneal; patterning gate, etching gate, and performing back end of line processing.

### FIELD OF INVENTION

The present invention relates generally to the fabrication of semiconductor devices and more particularly to methods for reducing in complementary metal oxide semiconductor (CMOS) fabrication the inversion oxide (TOX_{INV}) thickness without adding additional patterning process steps.

### BACKGROUND OF THE INVENTION

Integrated circuits are manufactured by fabricating electrical devices on semiconductor substrates and interconnecting the various electrical devices. Field effect transistors (FETs) are commonly utilized for switching, logic, amplification, filtering, and the like, associated with both analog and digital electrical signals. One of the most common devices among these are metal-oxide-semiconductor field-effect transistors (MOSFETs), wherein a gate contact is energized to create an electrical field within a channel region of a semiconductor body or bulk region, wherein electrons are induced to travel within the channel between a source and a drain of the semiconductor body. The source and drains are normally fabricated by introducing dopants into the preferred regions on either side of the channel. A thin gate dielectric/insulator or gate oxide is formed over the channel, and a gate electrode or gate contact is formed on top of the gate dielectric. The gate dielectric and gate electrode layers are then patterned to form a gate structure overlying the channel region of the substrate, for example, using an etching process.

The threshold voltage (Vt) is the gate voltage value required to make the channel conductive by formation of an inversion layer at the surface of the semiconductor channel. The inversion layer is a region of the channel near the surface of a semiconductor underlying the gate where a p- or n-type semiconductor material contacts the bulk of the semiconductor, which is of an opposite type.

Complimentary-metal-oxide-semiconductors (CMOS) devices are widely used in the semiconductor industry, wherein both n-channel and p-channel (NMOS and PMOS) transistors are fabricated to create logic devices, switches, and the like. For enhancement-mode (e.g., normally off) devices the threshold voltage Vt is positive for NMOS and negative for PMOS transistors. The threshold voltage is dependent upon the flat-band voltage, where the flat-band voltage depends on the work function difference between the gate and the substrate materials, as well as on surface charge.

A material's work function is the minimum energy (usually measured in electron volts ((eV)) needed to remove an electron from the material to a point immediately outside the material's surface. For CMOS devices, it is advantageous to provide expected, repeatable, and stable threshold voltages (Vt) for the NMOS and PMOS transistors. To establish Vt values, the work functions of the PMOS and NMOS gate contact and the corresponding channel materials are independently tuned or adjusted through gate and channel engineering, respectively.

Gate engineering is employed in combination with channel engineering to adjust the work function of the gate contact materials, where different gate work function values are set for PMOS and NMOS gates. The work function of polysilicon can be easily raised or lowered by doping the polysilicon with p-type or n-type impurities, respectively. The PMOS polysilicon gates are typically doped with p-type impurities and NMOS gate polysilicon is doped with n-type dopants, typically during implantation of the respective source/drain regions following gate patterning. In this way, the final gate work functions are typically near the Si conduction band edge for NMOS and near the valence band edge for PMOS. The provision of dopants into the polysilicon also has the benefit of increasing the conductivity of the gate contact. Polysilicon has thus far been widely using in the fabrication of CMOS devices, wherein the gate engineering (e.g., implants) are conventionally tuned to provide a desired gate contact conductivity (e.g., sheet resistance value), and the threshold voltage fine tuning is achieved by tailoring the Vt adjust implants to change the channel work function.

A traditional or prior art CMOS fabrication approach is illustrated in FIGS. 1-7. Referring initially to FIG. 1, a substrate 102 can comprise a silicon substrate, silicon epitaxial layer, and the like, used to form a CMOS device 100 according to a conventional process. A thin silicon oxide layer can be formed on the surface of the substrate 102 to serve as an etching mask. The silicon oxide layer can be grown from the semiconductor substrate 102 using thermal oxidation, for example. Alternatively, the silicon oxide layer can be deposited by using low pressure chemical vapor deposition (LPCVD). A photoresist with a trench pattern can then be formed on the silicon oxide layer using traditional techniques. The trench pattern can be defined using conventional photolithography including photoresist coating, ultra violet (UV) exposure, development and chemical removal. The shallow trench isolation (STI) device 104 as illustrated in FIG. 2 may be formed according to any conventional method of fabrication of STI known by those of ordinary skill in the art. Shallow trench isolation (STI), typically involves trenches that are etched and filled, for example, with single or multiple isolation, low-k or dielectric materials. The isolation materials can be, for example silicon dioxide (SiO₂), ZrO₂, Al₂O₃, high density plasma (HDP) oxide, combinations thereof, and the like. FIG. 2 illustrates an STI trench recess wherein the depth, for example, is approximately 80 nanometers (nm). A trench width corresponding to a width in the trench at the top of the isolation material can be about 40-200 nanometers wide, for example. A dry etching process can be performed to etch the thick silicon oxide layer and expose the trench regions of the semiconductor substrate 102. Reactive ion etching (RIE) with plasma gases containing fluoride such as CF₄, C₂F₆ or C₃F₈ is preferable for this anisotropic etching. Chemical mechanical polishing (CMP) is then performed in FIG. 2 to globally planarize the surface, as shown, completing the STI 104. The formation of STI is well known by those of ordinary skill in the art.

Referring now to FIG. 3, an N-channel threshold voltage (hereinafter referred to as “VT_{N}”) pattern 106 is formed over a pad oxide 108 that was deposited on top of a substrate 102. The pattern 106 protects the PMOS device. An VT_{N} ion implantation 114 is performed to adjust a threshold voltage (hereinafter referred to as “VT_{N}”). Subsequently, an N-channel punchthrough implantation 116 is conducted to prevent punchthrough in the NMOS. An N-channel channel stop implant 118 is subsequently performed to isolate a field, increase VT_{N}, and decrease leakage current. A post implantation clean 119 is then performed, for example, a photoresist strip and a residue clean are typically needed after implantation in semiconductor fabrication processes. Conventional dry type strip and/or clean sequences typically use plasma to ash the photoresist and wet chemicals to clean off residues left over from the implantation process.

FIG. 4 illustrates a conventional CMOS fabrication process 100, a P-channel threshold voltage (hereinafter referred to as “VT_{P}”) pattern 120 is formed over the substrate 102. The pattern 120 protects the NMOS device from damage. An VTₚ ion implantation 122 is performed to adjust a P channel threshold voltage (“VTₚ”). Then a P-channel punchthrough implant 124 is conducted and an N-channel channel stop implant 126 is performed to isolate a field, increase VTₚ, and decrease leakage current, as discussed supra. A post implant clean 128 is then performed to remove photoresist and other contaminants. A conventional dry type strip and/or clean sequences can be used as discussed supra.

A thermal anneal 130 is performed in FIG. 5 in order to correct damage caused by the ion implantations performed in FIGS. 3 and 4. The ion implantations are used to introduce dopants to the substrate during manufacture and the dose and energy of the ionic species can be controlled very accurately. However, a drawback of ion implantation is the creation of damaged regions within the semiconductor that include defects in the silicon lattice or other layers, such as oxide, nitride or polysilicon layers, which can have adverse effects on transistor fabrication at later steps. One commonly known defect is the creation of amorphous silicon which must be annealed to return it to its crystalline state. The thermal anneal 130, in FIG. 5 is followed by conventional gate oxide and polysilicon depositions, 136 and 138, respectively. The gate oxide deposition 136 and the polysilicon deposition 138 are well known by those of ordinary skill in the art. FIG. 6 further illustrates the fabrication of a current or traditional CMOS 100 device. The polysilicon is patterned 140 and etched 142, as illustrated. These techniques are well known by those of ordinary skill in the art. The CMOS device 100 then goes through back end of the line processing (BEOL), well known by those of ordinary skill in the art in order to complete the device 100. FIG. 7 illustrates a conventional CMOS fabrication process 700 beginning at 701, in which STI formation and processing is performed at 702 within the silicon substrate, including trench formation and isolation processing. At 704 patterning of the VT_{N} implantation can be performed and at 706, channel engineering is performed (e.g., Vt adjust, punchthrough, and channel stop implants) for an NMOS. A post implantation clean is performed at 708, for example, a photoresist strip and a residue clean are typically needed after implantation in semiconductor fabrication processes. Conventional dry type strip and/or clean sequences typically use plasma to ash the photoresist and wet chemicals to clean off residues left over from the implantation process. At 710 patterning of VT_{P} can be performed and at 712, channel engineering is performed (e.g., Vt adjust, punchthrough, and channel stop implants) for a PMOS device. At 714 an additional post implantation clean is performed followed by a well implant damage anneal at 716. A thin gate dielectric or oxide and an overlying polysilicon layer are formed at 718 and 720, respectively, and the polysilicon is patterned and etched at 720 and 722, respectively, to form gate structures for the prospective NMOS and PMOS transistors. Highly-doped drain (HDD) implants and deep source/drain implants are performed at 724 to provide p-type dopants to prospective source/drains of the PMOS regions and n-type dopants to source/drains of the NMOS regions, using the patterned gate structures and isolation structures as an implantation mask.

At 724, the PMOS source/drain regions and the PMOS polysilicon gate structures are implanted with p-type dopants to further define the PMOS source/drains, and to render the PMOS gates conductive. Similarly, the NMOS source/drain regions and the NMOS polysilicon gate structures are implanted at 724 with n-type dopants, further defining the NMOS source/drains and rendering the NMOS gates conductive. Thereafter, the source/drains and gates are silicided at 726 and back end processing (e.g., interconnect metallization, etc.) is performed at 726 as well, before the process 700 ends at 728. In the conventional process 700, the channel engineering implants shift the work functions of the PMOS and NMOS channel regions, respectively, to compensate for the changes in the PMOS and NMOS polysilicon gate work functions resulting from the source/drain implants at 706 and 712, respectively. In this manner, the desired work function difference between the gates and channels may be achieved for the resulting PMOS and NMOS transistors, and hence the desired threshold voltages.

However, the approach discussed supra involves additional pattern levels in order to reduce TOX_{INV} (Inversion TOX) in CMOS flow. Accordingly, there is a need for improved CMOS transistor gate designs and fabrication techniques by which reduce TOX_{INV} (Inversion TOX) in CMOS flow without adding additional gate pattern steps.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to the more detailed description that is presented later. The prior art approach will be contrasted with the present invention as illustrated in FIGS. 8-14. FIGS. 1-6 are a series of cross-sectional side view drawings illustrating a prior art or traditional method for fabricating a CMOS device.

In one embodiment, the invention is directed to a method of fabricating a CMOS transistor, comprising forming shallow trench isolation regions in a workpiece, depositing a gate oxide layer on top of the workpiece, depositing a polysilicon layer on top of the gate oxide, performing VT_{N} patterning, performing first series of adjusted implantations, performing post implantation cleaning, performing VT_{P} patterning, performing a second series of adjusted implantations, performing the post implantation cleaning, performing a well implant damage anneal, patterning gate and performing back end of line processing.

In another embodiment, the present invention discloses a method of fabricating a CMOS transistor, comprising forming shallow trench isolation regions in a workpiece, depositing a gate oxide layer on top of the workpiece, depositing a polysilicon layer on top of the gate oxide, performing VT_{N} patterning, performing a first adjusted VT_{N} implantation, performing a first adjusted P_{WELL} implantation, performing a first adjusted channel stop implantation, performing a first adjusted punchthrough implantation, performing post implantation cleaning, performing VT_{P} patterning, performing a second adjusted VT_{P} implantation, performing a second adjusted N_{WELL} implantation, performing a second adjusted channel stop implantation, performing a second adjusted punchthrough implantation, performing the post implantation cleaning, performing well implant damage anneal, patterning gate, performing source/drain extensions, performing deep source/drain patterning, performing source/drain implantations, depositing silicide, forming contacts and performing back end of line processing.

### BRIEF DESCRIPTION OF THE DRAWINGS

FIG. 1 is a partial side view of a silicon substrate used in a traditional CMOS device fabrication process;

FIG. 2 is a partial side view of an STI trench formed in the substrate using a traditional fabrication process;

FIG. 3 is a side view in illustrating various implantations performed in a traditional CMOS device fabrication process;

FIG. 4 is a side view of a partially completed CMOS device fabricated using traditional processing techniques;

FIG. 5 is a side view illustrating traditional processing techniques utilized to form polysilicon gates on a CMOS device;

FIG. 6 is a side view of formed gates on a CMOS device utilizing traditional fabrication processes;

FIG. 7 is a flow diagram illustrating a traditional method of fabricating a CMOS device;

FIG. 8 is side view illustrating a substrate utilized to make a CMOS device, according to one embodiment of the invention;

FIG. 9 is a drawing illustrating a side view of shallow trench isolation structures formed in the substrate, according to another embodiment of the present invention;

FIG. 10 is a side view illustrating polysilicon deposition and ion implantation of the CMOS device, according to yet another embodiment of the present invention;

FIG. 11 is a side view illustrating the additional ion implantation of the CMOS device, according to another embodiment of the present invention;

FIG. 12 is a side view illustrating the CMOS device in FIG. 10 with the photoresist removed, according to yet another embodiment of the present invention;

FIG. 13 is a partial side elevation view illustrating the CMOS in FIG. 11 with the gates formed on the substrate, according to another embodiment of the invention;

FIG. 14 is a flow diagram illustrating an exemplary method of fabricating CMOS devices in a semiconductor substrate, according to an aspect of the present invention.

### DETAILED DESCRIPTION OF THE INVENTION

One or more implementations of the present invention will now be described with reference to the attached drawings, wherein the reference numerals are used to refer to like elements throughout, and wherein various structures are not necessarily drawn to scale. The method of the present invention will be described with reference to the formation of CMOS transistors. However, the method is applicable to other processes, for example, a process for forming any suitable digital or analog electronic device, for example, memory devices, logic devices, microprocessors, microcontrollers, and the like. Furthermore, while the following detailed description is presently contemplated by the inventors for practicing the invention, it should be understood that the description of this embodiment is merely illustrative and that it should not be taken in a limiting sense.

The present invention provides for an improved method of fabricating CMOS transistors that reduces TOX_{INV} for transistor I_{ON} performance improvement without adding additional patterning. By tailoring of threshold voltage (Vt), well, channel-stop, and punchthrough implantations and dopant profiles the present invention can be “tuned” to that of a CMOS fabricated using traditional flow. The invention eliminates the need of separate pre-gate doping implantation patterning (e.g., cost reduction) without sacrificing the CMOS transistor performance in high performance CMOS flows. In low-cost CMOS flow, the present invention allows improved CMOS transistor performance without the added cost of pre-gate doping patterns.

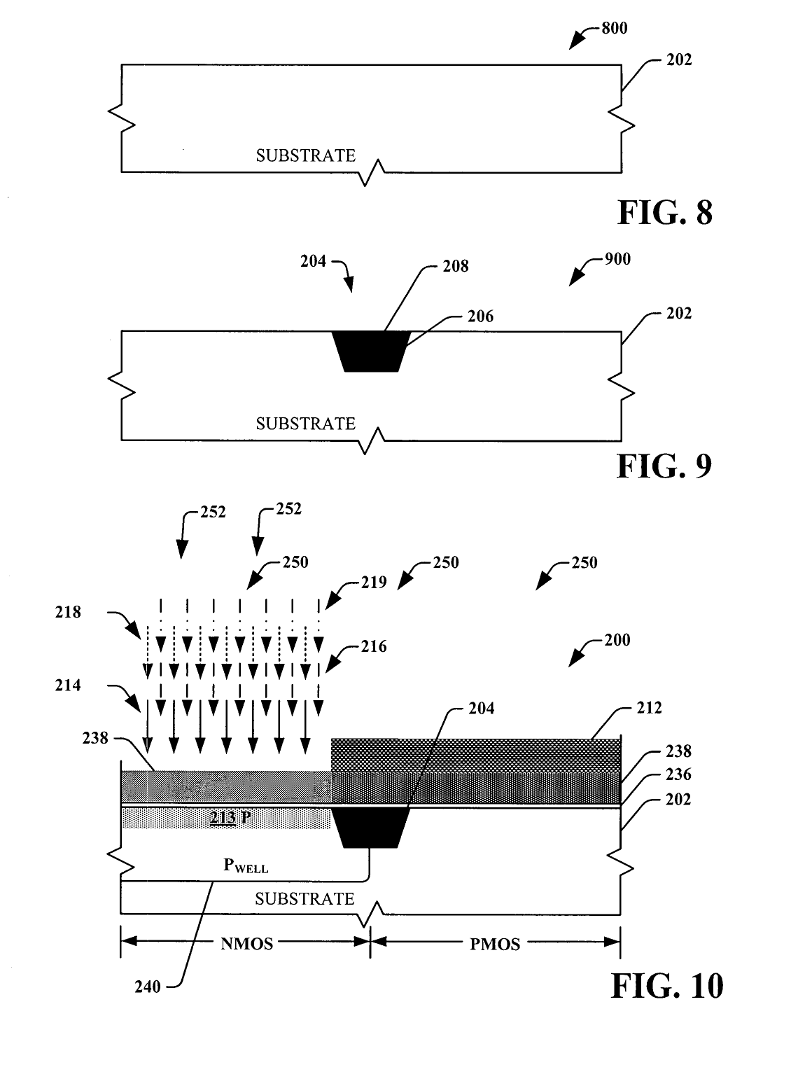

FIG. 8 is a cross sectional side view of a substrate 202 employed in fabricating a semiconductor device 200, according to one embodiment of the present invention. It is to be appreciated that reference to substrate, workpiece, wafer or semiconductor substrate 202 as used herein can include a base semiconductor substrate 202 (e.g., silicon, gallium arsenide (GaAs), silicon germanium (SiGe), or a silicon on wafer (SOI) and any epitaxial layers or other type semiconductor layers formed thereover or associated therewith. It is to be further appreciated that elements depicted herein are illustrated with particular dimensions relative to one another (e.g., layer to layer dimensions and/or orientations) for purposes of simplicity and ease of understanding and that actual dimensions of the elements may differ substantially from that illustrated herein. It is to be further yet appreciated that the semiconductor substrate 202 in FIG. 8 upon which the CMOS is fabricated can be doped with a p-type impurity such as boron, for example, to establish a initial threshold adjustment implant region therein.

FIG. 9 illustrates a shallow trench isolation (STI) structure 204 formed in a semiconductor device 200 according to yet another embodiment of the present invention. The drawing illustrates, for example, the silicon substrate 202, a silicon trench 206, a trench liner oxide layer (not shown) and an oxide layer 208 that are well know by those of ordinary skill in the art. The isolation trench deposition process performed in FIG. 9 may be performed, for example, using any appropriate deposition process, such as high density plasma chemical vapor deposition (HDPCVD) of silicon oxide (SiO₂), low pressure chemical vapor deposition (LPCVD), tetraethyl-orthosilicate (TEOS) deposition, plasma enhanced chemical vapor deposition (PECVD), and the like, followed by chemical mechanical polishing and cleaning operations. However, it is to be appreciated that any deposition method or process may be employed, and that other fill materials and fill processes are contemplated as falling within the scope of the invention. As discussed supra, there are known techniques of etching, sputtering, deposition, chemical mechanical polishing and cleaning associated with semiconductor STI manufacturing that are well known by those of ordinary skill in the art. Of course, those skilled in the art will recognize many modifications may be made to this STI configuration, without departing from the scope or spirit of what is described herein. Other isolation techniques known by those of ordinary skill in the art may be used, e.g., LOCOS, and the like.

FIG. 10 illustrates a cross sectional side view of a semiconductor CMOS device 200, according to yet another embodiment of the present invention. A gate oxide layer 236 can be applied on top of the substrate surface 202 utilizing techniques well know by those of ordinary skill in the art. A polysilicon layer 238 is shown deposited on the gate oxide layer 236, for example. The polysilicon layer 238 can be deposited using conventional techniques, known by those of ordinary skill in the art, discussed supra. The polysilicon layer 238 can be, for example, deposited employing high density plasma (HDP) deposition, low pressure chemical vapor deposition (LPCVD), rapid thermal chemical vapor deposition (RTCVD), plasma enhanced chemical vapor deposition (PECVD), and the like. The CMOS fabrication process continues by using conventional photolithographic and reactive ion etch procedures, for example, to create an N-channel threshold voltage (hereinafter referred to as “VT_{N}”). The N-channel threshold voltage (turn on voltage) is a measure of the occurrence of the inversion layer in the N-channel of the CMOS transistor. Photoresist 212 can be deposited over the polysilicon 238, shown in FIG. 10, for example. A subsequent reactive ion etch procedure 252 can be accomplished utilizing a etching environment, an etchant or various etchants, for example, well known by those of ordinary skill in the art. At the conclusion of the reactive ion etch process 252 the remaining photoresist 212, still present, is removed via a cleaning process 250 well known by those of ordinary skill in the art.

First adjusted VT_{N} implantation 214, P_{WELL} implantation 216, channel-stop implantation 218 and punchthrough implantation 219 are performed utilizing known techniques. However, the first adjusted implantations dope only the polysilicon layer 238 and do not pass through the layer 238. The inventors recognized that by performing the implantations in this manner it avoids having to perform additional patterning steps. The VT_{N} implantation mask 212 is patterned using deposition of photoresist and suitable lithographic techniques as are known by those of ordinary skill in the art. The mask 212 allows the selective exposure of the N-channel portion 213 of the substrate. The N-channel threshold voltage (VT_{N}) adjustment implantation 214 is employed, for example, to implant boron in the N channel portion 213. A subsequent first adjusted P_{WELL} implantation 216 can be performed, wherein NMOS transistors are fabricated in the P_{WELL} regions. N-well's are formed, for example, by ion implantation, deposition, diffusion, and the like. Lateral diffusion of ions limits the proximity between structures and therefore P_{WELL} ion implantation 216 results in shallower wells compatible with today's fine line semiconductor processing and is well known by those of ordinary skill in the art.

A first adjusted channel-stop implantation 218 makes the regions between the source and drains harder to invert, for example. The channel stop implantation 218 can be performed., for example, with ions of sufficient energy by which the ions pass through a partial isolation oxide film and a peak impurity profile is generated in the silicon on insulator (SOI) layer, thereby forming a channel-stop layer in the silicon on insulator layer under the fractional isolation oxide film. At this time, the impurity of channel-stop implantation is not stopped in the SOI layer corresponding to the active region. A first adjusted punchthrough implantation 218 can be performed into the substrate below the gate recess and the pad oxide layer 236 can then be isotropically etched to remove the oxide layer 236 at the bottom of the gate recess and a gate dielectric layer is grown in the bottom of the gate recess. Gate polysilicon can subsequently be deposited covering the top surface and filling the gate recess.

The post implantation clean 250 can then be performed on the CMOS device 200. A photoresist strip and residue clean can be conducted after the various implantation processes are completed in the fabrication process. Conventional dry type strip and/or clean sequences typically use plasma to ash the photoresist and wet chemicals to clean off residues left over from the process.

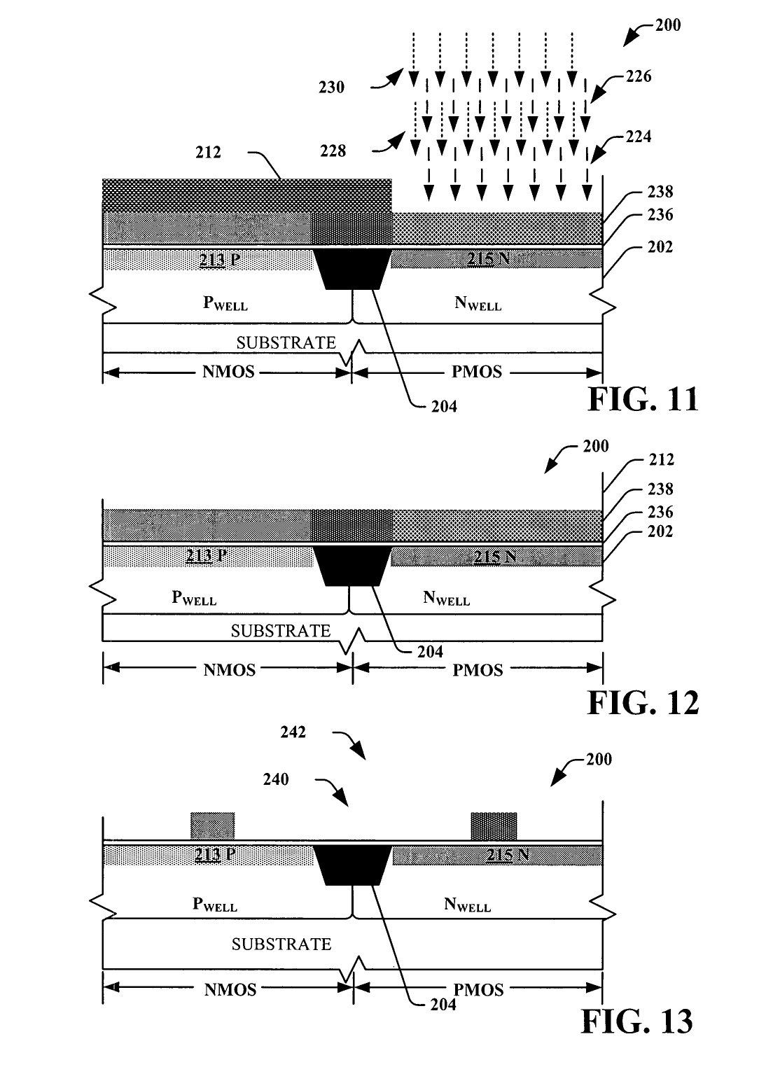

FIG. 11 illustrates a side view of partially completed CMOS device 200 wherein a second adjusted VT_{P} implantation pattern 228 or mask can be formed using deposition of photoresist and appropriate lithographic techniques as are known by those of ordinary skill in the art. An second adjusted threshold voltage (VT_{P}) adjustment implantation process 224 can be employed to implant an ionic species (e.g., boron) in the exposed portions of the N_{WELL} 215 and the source/drain transistor region using the mask 212, for example. The second adjusted implantations are modified such that the second adjusted implantation ions pass through the polysilicon and dope the silicon, for example. The process provides P type dopant to the P channel region of the first transistor region near the upper surface 215 of the N well to thus adjust the threshold voltage of a first transistor formed therein, as further illustrated and described supra.

A second adjusted channel stop implant 226 is also executed wherein ions pass through a isolation gate oxide 236 and the polysilicon layer 238 and an impurity profile is generated thereby forming a channel stop layer under the oxide layer 236 and the polysilicon layer 238 that acts as an isolation region. A channel stop region involves the second adjusted ion implantation of an impurity having the same conductivity as the impurity in the semiconductor substrate. The areas that do not contain transistors can be masked with a photoresist mask and doped so that the doped region, in conjunction with the STI that covers these areas, aids in preventing conduction between unrelated transistor source/drains. A second adjusted punchthrough implantation 226 is performed. As mentioned supra, the drain current of a MOS transistor will increase in some cases in which a parasitic current is created between the source and drain. This portion of the drain current is poorly controlled by the gate contact since the current path is located deeper in the bulk region, farther away from the gate. This can add to the sub-threshold leakage current leading to increased power consumption. The second adjusted punchthrough implant 226 is thus performed to reduce these parasitic currents.

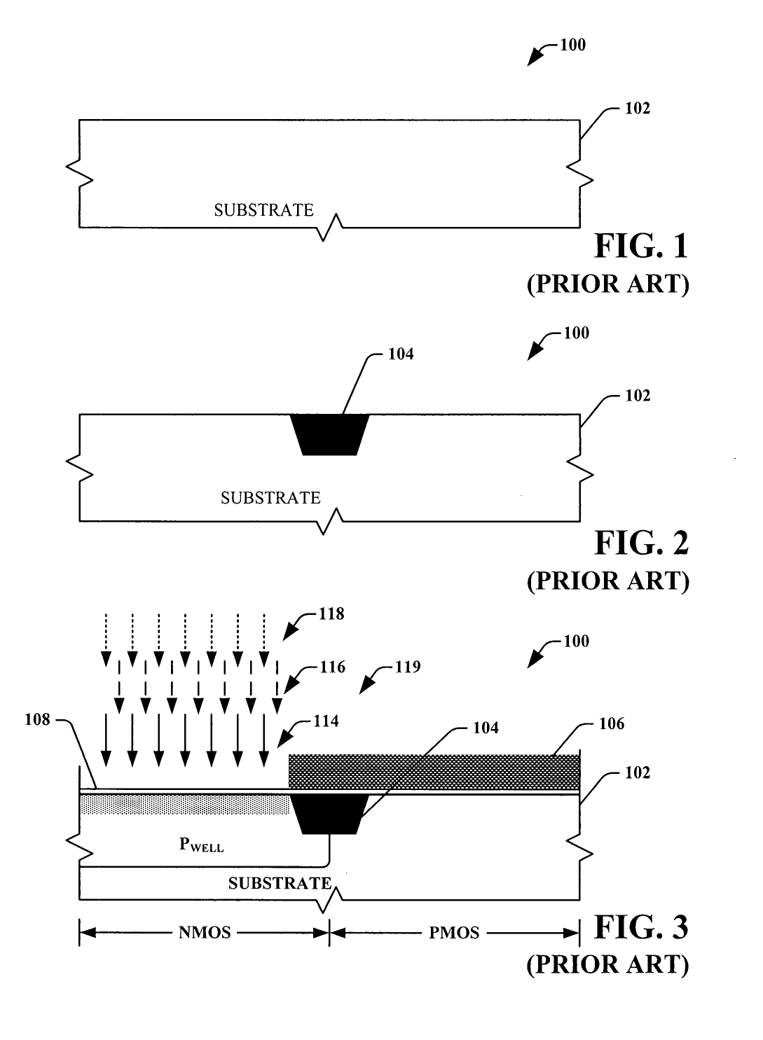

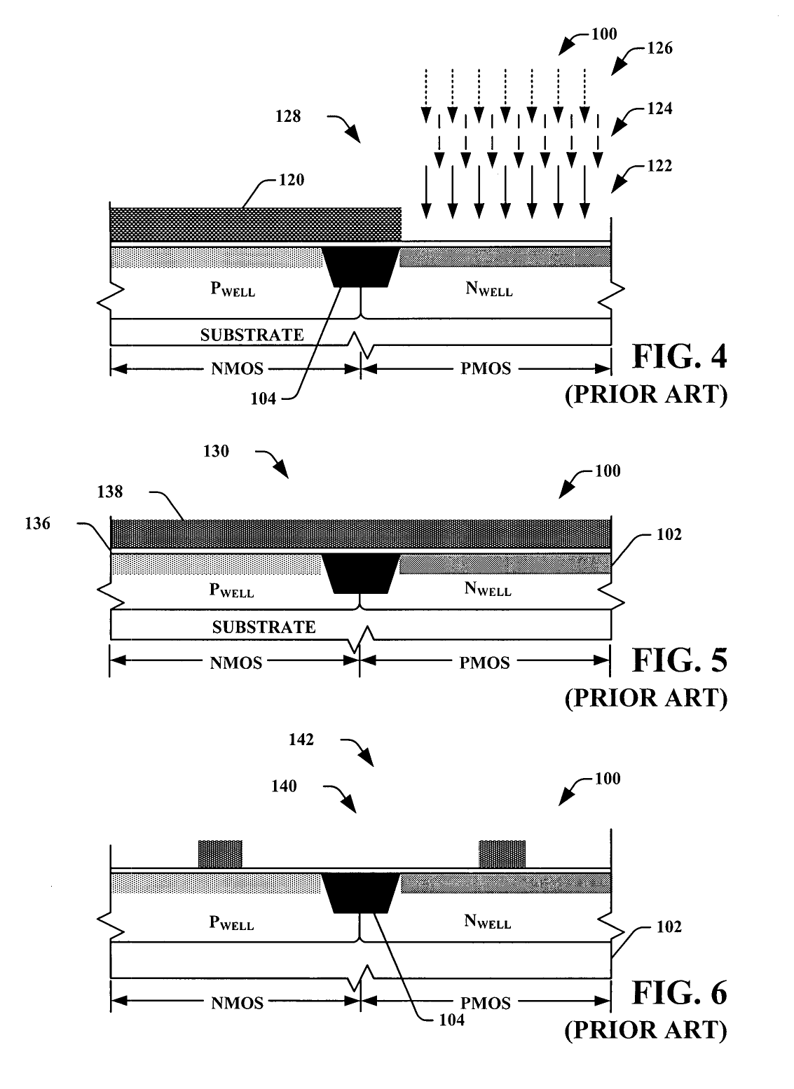

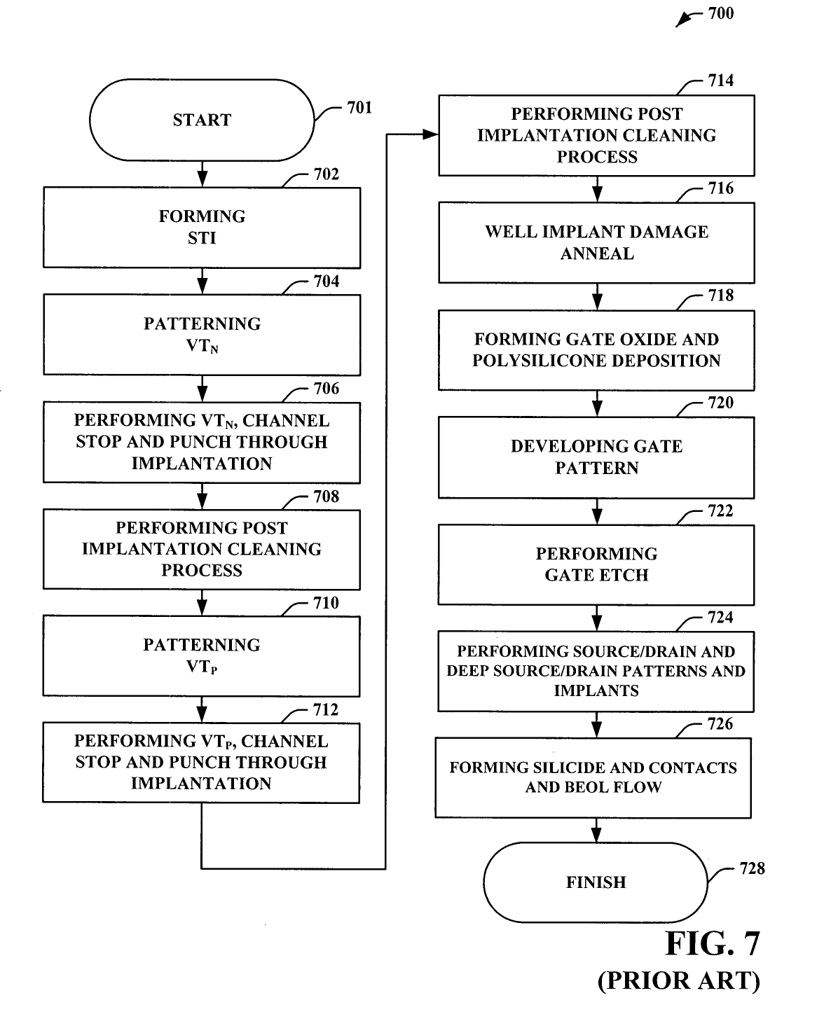

A combination of plasma ashing 240 and wet cleaning 242 can be used to remove the photoresist mask remaining after etching and/or the various implantation steps. The VT_{P} patterning can be utilized using known lithographic techniques, to create the PMOS in the N_{WELL}, as illustrated in FIG. 13, for example. The various second adjusted implantations are performed through the polysilicon layer and the gate oxide layer. This is a different approach than that which was carried out in FIGS. 1-6. In the FIGS. 1-6 (the traditional or prior art approach) process the Vt, channel stop, and punchthrough implantations were performed prior to the polysilicon gate patterning and etching.

The post implant cleaning process 240 and 242 can be utilized to remove left over photoresist, as discussed supra. The post implant cleaning process is well known by those of ordinary skill in the art. An annealing or heat treatment can be performed to repair well implant damage caused by the atomic collisions taking place during implantation. Ion implantation is routinely followed by an annealing process (e.g., rapid thermal annealing (RTA)) which restores the crystal lattice and “activates” the implanted atoms. The polysilicon layer can be patterned, for example, by applying a layer of photoresist, exposing the layer of photoresist to ultraviolet light through a mask prepared for this purpose. The photoresist can be selectively “activated” and removed by developing it and etching both polysilicon and exposed oxide in the areas wherein the photoresist is removed. The remaining photoresist masks both the gate areas, gates of peripheral transistors, interconnections, and the like.

A source/drain extension implantation is performed in FIG. 13. The source/drain regions can generally include an extension region that is disposed partially underneath the gate to improve the transistor performance. Shallow source/drain extensions help to achieve immunity to short-channel effects which degrade transistor performance for both N-channel and P-channel transistors within the CMOS. Short-channel effects can cause threshold voltage roll-off, drain-inducted barrier-lowering, and the like. The extensions for controlling short-channel effects, are particularly important as transistors become smaller and smaller. In addition in FIG. 13, sidewall spacers can be formed on the side surfaces of the gate, followed by ion implantation to form deep source/drain implants. Annealing can then be utilized to activate the deep source/drain regions prior to removal of the first sidewall spacers, for example.

Silicide layers can be formed on the substrate surface and gate electrode, for example. The contact to source and drain regions can made by forming the TiSi₂ layer on top of the regions by sputtering, for example, followed by an annealing process to form the silicide. The remaining Ti on the surface of the wafer, which does not contact the Si can be wet etched removed, leaving self aligned contacts.

Other processes, such as thermal processes can also be performed and are well known by those of ordinary skill in the art. For example, a rapid thermal anneal can be performed that activates implanted dopants within the source/drain regions. Additionally, for example, suitable silicide regions can be comprised of cobalt (Co), and the like. The silicide regions generally provide a lower contact resistance to the polysilicon gate layer. Subsequently, interlayer dielectric layers and/or other insulative layers can be formed and contacts selectively formed therein. Other layers, including protective layers and metallization layers, can then be performed to complete fabrication of the device, as part of BEOL processing.

Although the fabrication process is illustrated and described herein as a series of steps, acts or events, it will be appreciated that the present invention is not limited by the illustrated ordering of such acts or events. For example, some fabrication steps or acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. The fabrication process begins by slicing silicon crystal structures into thin wafers and then adding material or removing material with regard to the wafer, for example, one at a time.

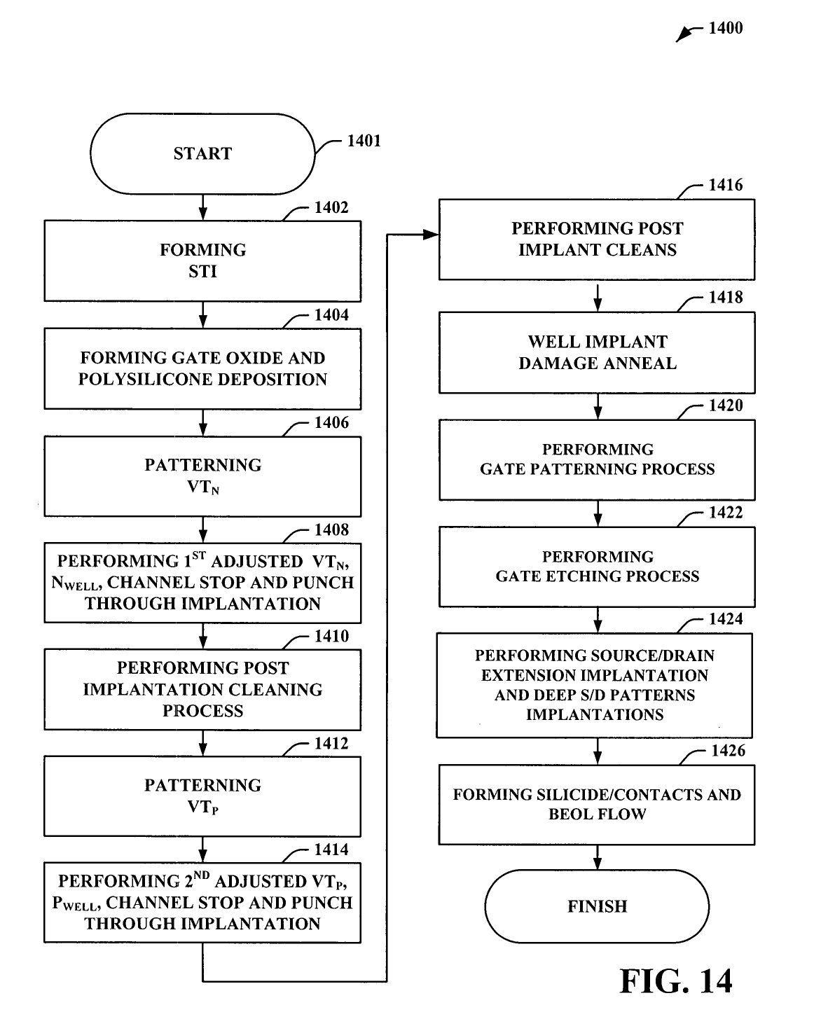

The process illustrated in FIG. 14 begins at 1401, wherein at 1402 a semiconductor substrate or wafer 102 (FIG. 8) that is the first building block or component in the overall CMOS transistor. The substrate can be, for example, silicon (Si), silicon-germanium (SiGe), and the like. The present process involves etching isolation trenches into the substrate 102 (FIG. 9) and resultant trenches at the end of the process are partially filled with an isolation or low-k dielectric material.

An STI isolation structure is formed at 1402. A pad oxide layer can be formed on the top surface of a semiconductor substrate. A nitride layer can then be deposited on the pad oxide layer. Isolation trenches can then be etched through the nitride and pad oxide layers into the semiconductor substrate, for example. A layer of oxide can subsequently be deposited over the nitride layer and on the isolation trench surfaces. The oxide layer can then polished away through chemical and mechanical polishing wherein the substrate can be planarized, for example. The creation of STI structures is well known by those of ordinary skill in the art. A gate oxide layer and a polysilicon layer can be deposited at 1404. The depositions of gate oxide and polysilicon layers are well known by those of ordinary skill in the art.

A conventional photoresist can be applied at 1406, for example, to create a pattern within the photoresist for subsequent implantation processes. The photoresist can be, for example, a solvent-based, light-sensitive resin solution that is uniformly applied, for example, on the polysilicon layer of the wafer, utilizing a spin type process, and the like. The photoresist can, for example, be a chemical, negative photoresist that hardens when exposed to ultraviolet light or other light wavelengths and the unexposed photoresist can be dissolved by employing a developer solvent, leaving openings in the exposed photoresist. Another approach involves utilizing a positive photoresist that is initially insoluble, and when exposed to e.g., UV, mercury light, laser, x-rays, electron beam, etc., becomes soluble. After exposure, the photoresist can create the etch pattern needed to form STI trenches during, for example, reactive ion etching (RIE).

At 1406, for example, exposing the layered substrate to ultraviolet light after an outer surface has been coated with a uniform layer of photoresist and the photoresist has been cured sufficiently, in order to define regions of the CMOS device. The device can be exposed by employing, for example, the ultraviolet light through a pattern mask opening, for example. The mask can be, for example, a glass plate on which an image corresponding to the circuit design is registered. The photoresist can be positive photoresist, negative photoresist, or both. Depending on the type of the photoresist either the image or non-image portion of the photoresist can be removed in a photoresist developer. Utilizing positive photoresist at 1406 can result in exposed photoresist softening which can then be washed away utilizing a developing solution, for example.

The wafer after exposed photoresist, for example, has been removed in the selected regions, at 1406. Remaining photoresist has two basic functions; the first function is precise pattern formation and the second function is to provide protection for the device from chemical attack during subsequent etch processes. The photoactive ingredient of the photoresist allows the pattern to be formed after the unwanted portions of the uniformly distributed photoresist have been removed. The development process involves chemical reactions wherein unprotected or developed resist has been dissolved away in a development process. Development can be carried out, for example, by immersion developing, spray developing, puddle developing, and the like.

At 1408 an adjusted threshold voltage (VT_{P}) adjustment implantation process can be employed to implant an ionic species (e.g., boron) in the exposed portions of the N_{WELL} and the source/drain transistor region using the mask, for example. The process provides P type dopant to the P channel region of the first transistor region near the upper surface of the N well to thus adjust the threshold voltage of a first transistor formed therein, as further illustrated and described supra.

A channel stop implant can also be executed at 1408 wherein ions pass through the isolation gate oxide layer and the polysilicon layer and an impurity profile is generated thereby forming a channel stop layer under the oxide layer and the polysilicon layer that acts as an isolation region. A channel stop region involves the ion implantation of an impurity having the same conductivity as the impurity in the semiconductor substrate. The areas that do not contain transistors can be masked with a photoresist mask and doped so that the doped region, in conjunction with the STI that covers these areas, aids in preventing conduction between unrelated transistor source/drains. A punchthrough implant is performed at 1408. As mentioned supra, the drain current of a MOS transistor will increase in some cases in which a parasitic current is created between the source and drain. This portion of the drain current is poorly controlled by the gate contact since the current path is located deeper in the bulk region, farther away from the gate. This can add to the sub-threshold leakage current leading to increased power consumption. The punchthrough implant is thus performed to reduce these parasitic currents.

A combination of plasma ashing and wet cleaning can be used to remove the photoresist mask remaining at 1410 after etching and/or the various implantation steps. The VT_{P} patterning can be utilized using known lithographic techniques, to create the PMOS in the N_{WELL}, as illustrated in FIG. 14, for example. The various implantations are performed through the polysilicon layer and the gate oxide layer. As mentioned supra, this is a different approach than that which was carried out in FIGS. 1-6. In the FIGS. 1-6 (the traditional or prior art approach) process the Vt, channel stop, and punchthrough implantations were performed prior to the polysilicon gate patterning and etching.

A post implant cleaning process at 1410 can be utilized to remove left over photoresist, as discussed supra. The post implant cleaning process is well known by those of ordinary skill in the art. An annealing or heat treatment is performed to repair well implant damage caused by the atomic collisions taking place during implantation. Ion implantation is routinely followed by an annealing process (e.g., rapid thermal annealing (RTA)) which restores the crystal lattice and “activates” the implanted atoms. The polysilicon layer can be patterned, for example, by applying a layer of photoresist, exposing the layer of photoresist to ultraviolet light through a mask prepared for this purpose. The photoresist can be selectively “activated” and removed by developing it and etching both polysilicon and exposed oxide in the areas wherein the photoresist is removed. The remaining photoresist masks both the gate areas, gates of peripheral transistors, interconnections, and the like.

At 1412 a gate pattern and plasma etch can be performed. The substrate polysilicon is patterned with, for example a photoresist that can be reactive ion etched (RIE) in O₂. The vertical etch rate of the resist (not shown) can be varied linearly with, for example etch time, plasma power, and the like

An adjusted threshold voltage (VT_{P}) adjustment implantation process can be employed to implant an ionic species (e.g., boron) in the exposed portions of the N_{WELL} at 1414 and the source/drain transistor region using the mask, for example. The process provides P type dopant to the P channel region of the first transistor region near the upper surface of the N well to thus adjust the threshold voltage of a first transistor formed therein, as further illustrated and described supra.

A channel stop implant is also executed at 1414 wherein ions pass through a isolation gate oxide, the polysilicon layer and an impurity profile is generated thereby forming a channel stop layer under the oxide layer and the polysilicon layer that acts as an isolation region. A channel stop region involves the ion implantation of an impurity having the same conductivity as the impurity in the semiconductor substrate. The areas that do not contain transistors can be masked with a photoresist mask and doped so that the doped region, in conjunction with the STI that covers these areas, aids in preventing conduction between unrelated transistor source/drains. A punchthrough implant is performed. As mentioned supra, the drain current of a MOS transistor will increase in some cases in which a parasitic current is created between the source and drain. This portion of the drain current is poorly controlled by the gate contact since the current path is located deeper in the bulk region, farther away from the gate. This can add to the sub-threshold leakage current leading to increased power consumption. The punchthrough implant is thus performed to reduce these parasitic currents.

At 1416 a combination of plasma ashing and wet cleaning can be used to remove the photoresist mask remaining after etching and/or the various implantation steps. The VT_{P} patterning can be utilized using known lithographic techniques, to create the PMOS in the N_{WELL}, for example. The various implantations are performed through the polysilicon layer and the gate oxide layer. This is a different approach than that which was carried out in FIGS. 1-6. In the FIGS. 1-6 (the traditional or prior art approach) process the Vt, channel stop, and punchthrough implantations were performed prior to the polysilicon gate patterning and etching.

The post implant cleaning process at 1416 can be utilized to remove left over photoresist, as discussed supra. The post implant cleaning process is well known by those of ordinary skill in the art. An annealing or heat treatment can be performed at 1418 to repair well implant damage caused by the atomic collisions taking place during implantation. Ion implantation is routinely followed by an annealing process (e.g., rapid thermal annealing (RTA)) which restores the crystal lattice and “activates” the implanted atoms. The polysilicon layer can be patterned, for example, by applying a layer of photoresist, exposing the layer of photoresist to ultraviolet light through a mask prepared for this purpose. The photoresist can be selectively “activated” and removed by developing it and etching both polysilicon and exposed oxide in the areas wherein the photoresist is removed. The remaining photoresist masks both the gate areas, gates of peripheral transistors, interconnections, and the like.

A source/drain extension implantation is performed at 1424. The source/drain regions can generally include an extension region that is disposed partially underneath the gate to improve the transistor performance. Shallow source/drain extensions help to achieve immunity to short-channel effects which degrade transistor performance for both N-channel and P-channel transistors within the CMOS. Short-channel effects can cause threshold voltage roll-off, drain-inducted barrier-lowering, and the like. The extensions for controlling short-channel effects, are particularly important as transistors become smaller and smaller.

Silicide layers can be formed on the substrate surface and gate electrode, for example, at 1426. The contact to source and drain regions can made by forming the TiSi₂ layer on top of the regions by sputtering, for example, followed by an annealing process to form the silicide. The remaining Ti on the surface of the wafer, which does not contact the Si can be wet etched removed, leaving self aligned contacts.

Other processes, such as thermal processes can also be performed and are well known by those of ordinary skill in the art. For example, a rapid thermal anneal can be performed that activates implanted dopants within the source/drain regions. Additionally, for example, suitable silicide regions can be comprised of cobalt (Co), and the like. The silicide regions generally provide a lower contact resistance to the polysilicon gate layer. Subsequently, interlayer dielectric layers and/or other insulative layers can be formed and contacts selectively formed therein. Other layers, including protective layers and metallization layers, can then be performed to complete fabrication of the device, as part of BEOL processing.

Although the method 1400 is described with respect to a CMOS device, the method also includes forming multiple devices. Although the invention has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Additionally, the term “exemplary” is intended to mean an example and not as a best or superior example. Furthermore, to the extent that the terms “including”, “includes”, “having”, “has”, “with”, or variants thereof are used in either the detailed description and the claims, such terms are intended to be inclusive in a manner similar to the term “comprising”.

What is claimed is:

1. A method of fabricating a CMOS transistor, comprising:
forming shallow trench isolation regions in a workpiece;
depositing a gate oxide layer on top of the workpiece;
depositing a polysilicon layer on top of the gate oxide;
performing VT_{N} patterning;
performing first series of adjusted implantations;
performing post implantation cleaning;
performing VT_{P} patterning;
performing a second series of adjusted implantations;
performing the post implantation cleaning;
performing a well implant damage anneal;
patterning gate; and
performing back end of line processing.

2. The method of claim 1, wherein the CMOS transistor is selected from a group of devices comprising: image sensors, data converters, and transceivers.

3. The method of claim 1, wherein the first series of adjusted implantations is selected from a group comprising: VT_{N} implantation, P_{WELL} implantation, channel stop implantation, and punchthrough implantation.

4. The method of claim 1, wherein the second series of adjusted implantations is selected from a group comprising: VT_{P} implantation, N_{WELL} implantation, channel stop implantation, and punchthrough implantation.

5. The method of claim 1, wherein the first series of adjusted implantations is performed subsequent to gate deposition.

6. The method of claim 1, wherein the first implantation region is implanted with ions from a group comprising: boron and phosphorus.

7. The method of claim 1, wherein the second implantation region is implanted with ions from a group comprising: phosphorus and boron.

8. A method of fabricating a CMOS transistor, comprising:
forming shallow trench isolation regions in a workpiece;
depositing a gate oxide layer on top of the workpiece;
depositing a polysilicon layer on top of the gate oxide;
performing VT_{N} patterning;
performing a first adjusted VT_{N} implantation;
performing a first adjusted P_{WELL} implantation;
performing a first adjusted channel stop implantation;
performing a first adjusted punchthrough implantation;
performing post implantation cleaning;
performing VT_{P} patterning;
performing a second adjusted VT_{P} implantation;
performing a second adjusted N_{WELL} implantation;
performing a second adjusted channel stop implantation;
performing a second adjusted punchthrough implantation;
performing the post implantation cleaning;
performing well implant damage anneal;
patterning gate;
performing source/drain extensions;
performing deep source/drain patterning;
performing source/drain implantations;
depositing silicide;
forming contacts; and
performing back end of line processing.

9. The method of claim 8, wherein the first series of implantations is selected from a group comprising: VT_{N} implantation, P_{WELL} implantation, channel stop implantation, and punchthrough implantation.

10. The method of claim 8, wherein the second series of implantations is selected from a group comprising: VT_{P} implantation, N_{WELL} implantation, channel stop implantation, and punchthrough implantation.

11. The method of claim 8, wherein the first series of implantations is performed subsequent to gate deposition.

12. The method of claim 8, wherein the first implantation is executed with ions from a group comprising: boron and phosphorus.

13. The method of claim 8, wherein the second implantation region is implanted with ions from a group comprising: boron and phosphorus.
